(19) United States
(12) Patent Application Publication
(10) Pub. No.: US 2015/0144301 A1
(43) Pub. Date: May 28, 2015

(54) HEAT DISSIPATING DEVICE

(71) Applicant: Cooler Master (Hui Zhou) Co., Ltd., Huizhou (CN)

(72) Inventors: Chia-Yu Lin, Huizhou (CN); Tao Song, Huizhou (CN)

(21) Appl. No.: 14/503,377

(22) Filed: Sep. 30, 2014

(30) Foreign Application Priority Data
Nov. 26, 2013 (CN) 201310611881.6

(51) Int. Cl. H05K 7/20; F28F 3/00

(52) U.S. Cl. CPC H05K 7/20409; F28F 3/00
USPC 165/80.1

(57) ABSTRACT

A heat dissipating device includes a base and a heat dissipating fin. The base includes an accommodating recess formed thereon. The heat dissipating fin includes a heat dissipating portion and a fixing portion, wherein the heat dissipating portion extends from the fixing portion, and the fixing portion has a first recess structure. The base and the heat dissipating fin are combined with each other by a punching process, such that the fixing portion is fixed in the accommodating recess in a tight-fitting manner and a first side wall of the accommodating recess is embedded in the first recess structure.

### BACKGROUND OF THE INVENTION

1. Field of the Invention

The invention relates to a heat dissipating device and, more particularly, to a heat dissipating device utilizing a punching process to combine a base and a heat dissipating fin.

2. Description of the Prior Art

Heat dissipating device is a significant component for electronic products. When an electronic product is operating, the current in circuit will generate unnecessary heat due to impedance. If the heat is accumulated in the electronic components of the electronic product without dissipating immediately, the electronic components may get damage due to the accumulated heat. Therefore, the performance of heat dissipating device is a significant issue for the electronic product.

Referring to FIG. 1, FIG. 1 is a schematic view illustrating a heat dissipating device 1 of the prior art. As shown in FIG. 1, a heat dissipating fin 12 is disposed on a base 10 of the heat dissipating device 1, and the heat dissipating fin 12 is formed with the base 10 integrally by a die casting process. Due to the requirement of mold stripping during the die casting process, the heat dissipating fin 12 has a draft angle α between 2 degrees and 3 degrees, such that the whole weight of the fin is heavy and the height of the fin is limited. Furthermore, the number of heat dissipating fins is reduced in the heat dissipating device due to the draft angle α, such that the heat dissipating area is not enough and the heat dissipating efficiency is worse.

### SUMMARY OF THE INVENTION

The invention provides a heat dissipating device utilizing a punching process to combine a base and a heat dissipating fin, so as to solve the aforesaid problems.

According to an embodiment of the invention, a heat dissipating device comprises a base and a heat dissipating fin. The base comprises an accommodating recess formed thereon. The heat dissipating fin comprises a heat dissipating portion and a fixing portion, wherein the heat dissipating portion extends from the fixing portion, and the fixing portion has a first recess structure. The base and the heat dissipating fin are combined with each other by a punching process, such that the fixing portion is fixed in the accommodating recess in a tight-fitting manner and a first side wall of the accommodating recess is embedded in the first recess structure.

As mentioned in the above, the invention utilizes the punching process to combine the base and the heat dissipating fin. After the punching process, the fixing portion of the heat dissipating fin is fixed in the accommodating recess of the base in the tight-fitting manner and the side wall of the accommodating recess of the base is embedded in the recess structure of the fixing portion of the heat dissipating fin, such that the base and the heat dissipating fin are combined with each other tightly. Accordingly, the draft angle of the conventional heat dissipating fin is unnecessary for the heat dissipating fin of the invention. Furthermore, the whole weight of the heat dissipating fin of the invention can be lighter and the height of the heat dissipating fin of the invention can be higher than the prior art. Moreover, the number of heat dissipating fins of the invention can be increased in the heat dissipating device, such that the heat dissipating area can be increased and the heat dissipating efficiency can be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a heat dissipating device of the prior art.

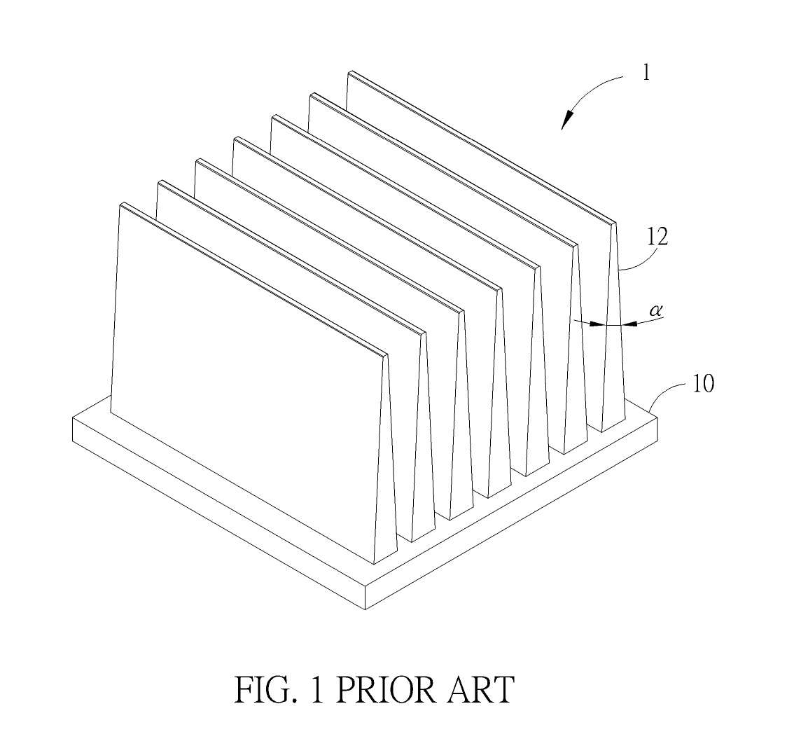

FIG. 2 is a perspective view illustrating a heat dissipating device according to a first embodiment of the invention.

FIG. 3 is an exploded view illustrating the base and one single heat dissipating fin shown in FIG. 2 before a punching process.

FIG. 4 is a flowchart illustrating a method of manufacturing the heat dissipating device shown in FIG. 2.

FIG. 5 is a perspective view illustrating a heat dissipating device according to a second embodiment of the invention.

FIG. 6 is an exploded view illustrating the heat dissipating device shown in FIG. 5 before the punching process.

### DETAILED DESCRIPTION

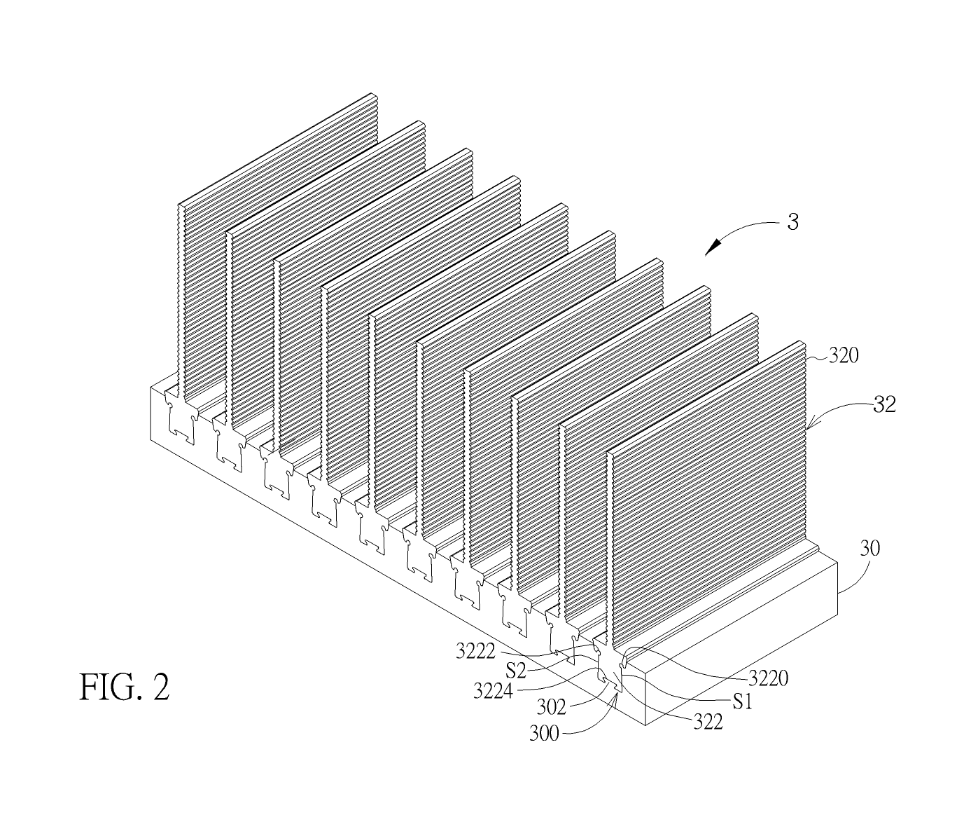

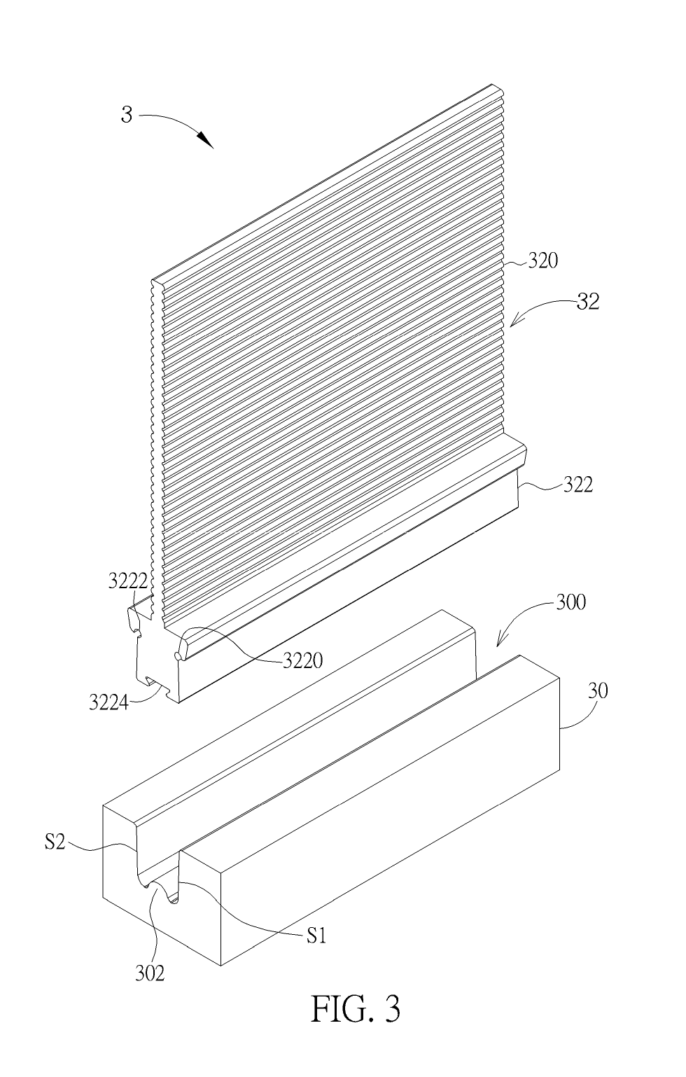

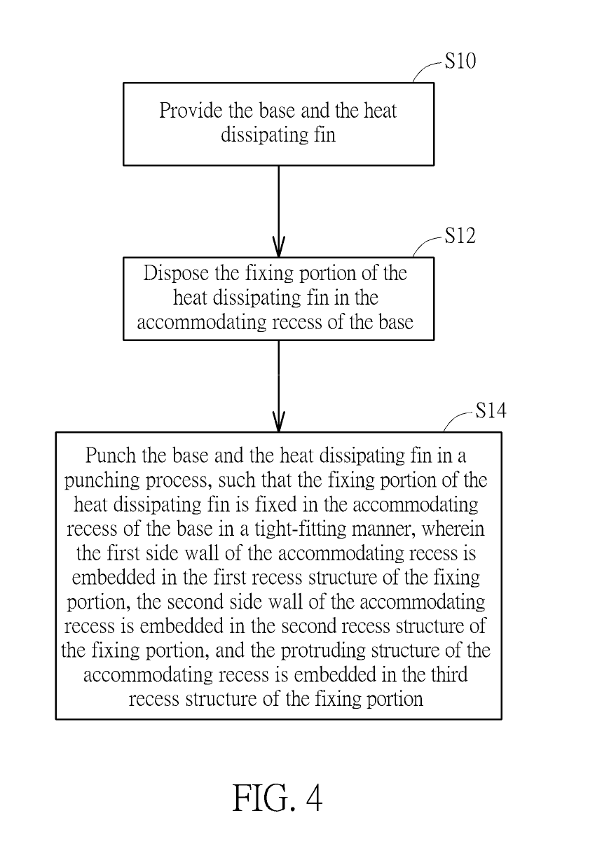

Referring to FIGS. 2 to 4, FIG. 2 is a perspective view illustrating a heat dissipating device 3 according to a first embodiment of the invention, FIG. 3 is an exploded view illustrating the base 30 and one single heat dissipating fin 32 shown in FIG. 2 before a punching process, and FIG. 4 is a flowchart illustrating a method of manufacturing the heat dissipating device 3 shown in FIG. 2.

As shown in FIG. 2, the heat dissipating device 3 of the invention comprises a base 30 and a plurality of heat dissipating fins 32, wherein the number of the heat dissipating fins 32 can be determined according to practical applications and are not limited to the embodiment shown in FIG. 2. The base 30 comprises an accommodating recess 300 and the accommodating recess 300 has a first side wall S1, a second side wall S2 and a protruding structure 302, wherein the first side wall S1 is opposite to the second side wall S2 and the protruding structure 302 is located between the first side wall S1 and the second side wall S2 of the accommodating recess 300. The heat dissipating fin 32 comprises a heat dissipating portion 320 and a fixing portion 322 and the heat dissipating portion 320 extends from the fixing portion 322. In this embodiment, the fixing portion 322 is, but not limited to, T-shaped.

In this embodiment, the fixing portion 322 has a first recess structure 3220, a second recess structure 3222 and a third recess structure 3224, wherein the first recess structure 3220 and the second recess structure 3222 are formed on opposite sides of the fixing portion 322, and the third recess structure 3224 is formed on a bottom of the fixing portion and located between the first recess structure 3220 and the second recess structure 3222. Furthermore, opposite sides of the heat dissipating portion 320 have symmetrical wave-shaped surface structures for increasing heat dissipating area. However, in another embodiment, opposite sides of the heat dissipating portion 320 may have asymmetrical wave-shaped surface structures according to practical applications. It should be noted that opposite sides of the heat dissipating portion 320 may have symmetrical or asymmetrical flat surface structures besides wave-shaped surface structures.

To manufacture the aforesaid heat dissipating device 3, first of all, step S10 shown in FIG. 4 is performed to provide the base 30 and the heat dissipating fin 32. In this embodiment, the base 30 and the heat dissipating fin 32 may be made of, but not limited to, aluminum. In another embodiment, a hardness of the heat dissipating fin 32 may be larger than a hardness of the base 30, so as to facilitate a punching process in the following. Furthermore, the heat dissipating fin 32 may be formed by an extrusion process or a die casting process according to practical applications. Afterward, step S12 shown in FIG. 4 is performed to dispose the fixing portion 322 of the heat dissipating fin 32 in the accommodating recess 300 of the base 30. Finally, step S14 shown in FIG. 4 is performed to punch the base 30 and the heat dissipating fin 32 in a punching process, such that the fixing portion 322 of the heat dissipating fin 32 is fixed in the accommodating recess 300 of the base 30 in a tight-fitting manner, wherein the first side wall S1 of the accommodating recess 300 is embedded in the first recess structure 3220 of the fixing portion 322, the second side wall S2 of the accommodating recess 300 is embedded in the second recess structure 3222 of the fixing portion 322, and the protruding structure 302 of the accommodating recess 300 is embedded in the third recess structure 3224 of the fixing portion 322.

In other words, the base 30 and the heat dissipating fin 32 are combined with each other by the punching process, such that the fixing portion 322 of the heat dissipating fin 32 is fixed in the accommodating recess 300 of the base 30 in the tight-fitting manner. After the base 30 and the heat dissipating fin 32 are combined with each other by the punching process, the first side wall S1 of the accommodating recess 300 deforms due to the impact in the punching process to be embedded in the first recess structure 3220 of the fixing portion 322, the second side wall S2 of the accommodating recess 300 deforms due to the impact in the punching process to be embedded in the second recess structure 3222 of the fixing portion 322, and the protruding structure 302 of the accommodating recess 300 deforms due to the impact in the punching process to be embedded in the third recess structure 3224 of the fixing portion 322. Accordingly, the base 30 and the heat dissipating fin 32 can be combined tightly.

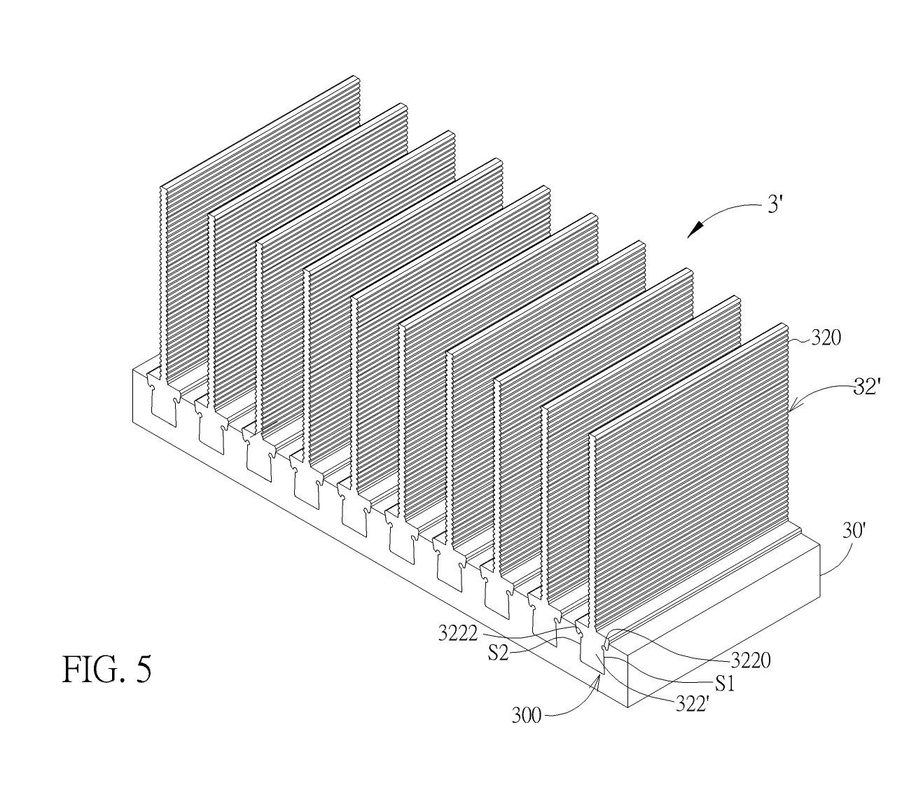

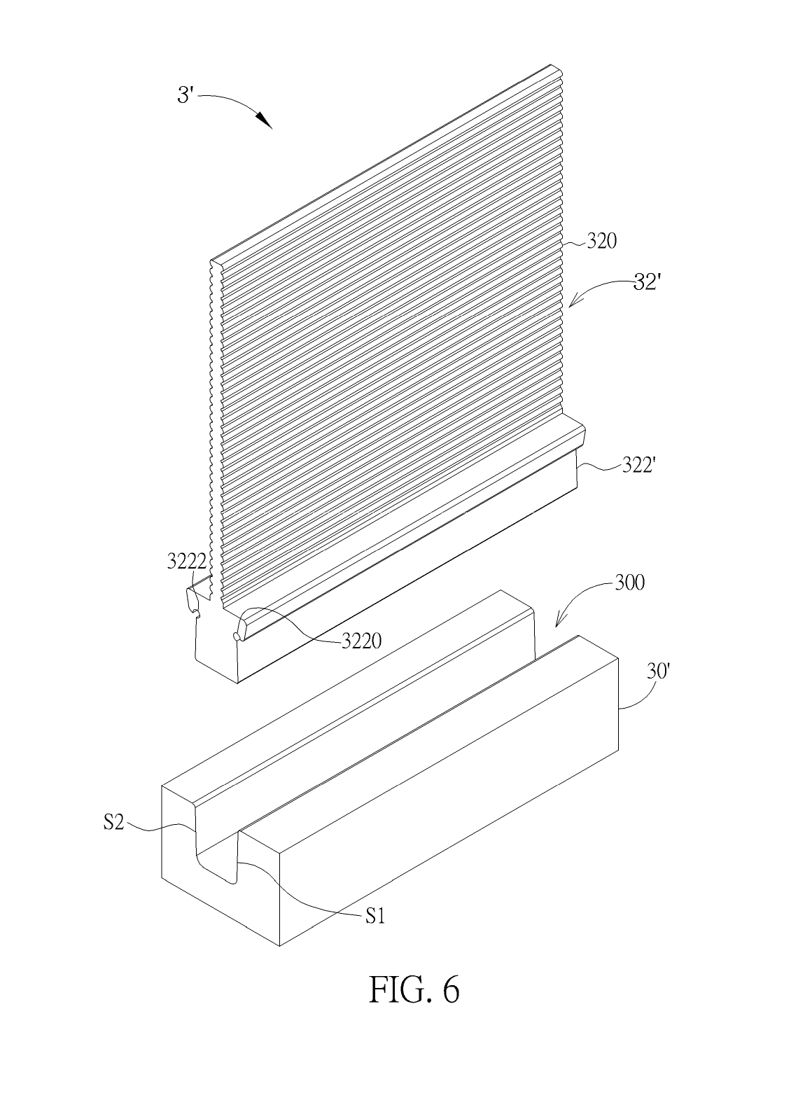

Referring to FIGS. 5 and 6 along with FIGS. 2 and 3, FIG. 5 is a perspective view illustrating a heat dissipating device 3′ according to a second embodiment of the invention, and FIG. 6 is an exploded view illustrating the heat dissipating device 3′ shown in FIG. 5 before the punching process. The difference between the heat dissipating device 3′ and the aforesaid heat dissipating device 3 is that the fixing portion 322′ of the heat dissipating fin 32′ of the heat dissipating device 3′ only has the first recess structure 3220 and the second recess structure 3222 without the aforesaid third recess structure 3224, and the base 30′ of the heat dissipating device 3′ does not have the aforesaid protruding structure 302, as shown in FIG. 6. Accordingly, the invention may only utilize the first recess structure 3220 and the second recess structure 3222 to combine the base 30′ and the heat dissipating fin 32′ tightly after the punching process, as shown in FIG. 5. It should be noted that the same elements in FIGS. 5-6 and FIGS. 2-3 are represented by the same numerals, so the repeated explanation will not be depicted herein again.

It should be noted that the fixing portion 322 of the heat dissipating fin 32 may only have the first recess structure 3220 or may only have the first recess structure 3220 and the third recess structure 3224 according to practical applications.

As mentioned in the above, the invention utilizes the punching process to combine the base and the heat dissipating fin. After the punching process, the fixing portion of the heat dissipating fin is fixed in the accommodating recess of the base in the tight-fitting manner and the side wall and/or the protruding structure of the accommodating recess of the base is embedded in the recess structure of the fixing portion of the heat dissipating fin, such that the base and the heat dissipating fin are combined with each other tightly. Accordingly, the draft angle of the conventional heat dissipating fin is unnecessary for the heat dissipating fin of the invention. Furthermore, the whole weight of the heat dissipating fin of the invention can be lighter and the height of the heat dissipating fin of the invention can be higher than the prior art. Moreover, the number of heat dissipating fins of the invention can be increased in the heat dissipating device, such that the heat dissipating area can be increased and the heat dissipating efficiency can be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat dissipating device comprising:
a base comprising an accommodating recess formed thereon; and
a heat dissipating fin comprising a heat dissipating portion and a fixing portion, the heat dissipating portion extending from the fixing portion, the fixing portion having a first recess structure, the base and the heat dissipating fin being combined with each other by a punching process, such that the fixing portion is fixed in the accommodating recess in a tight-fitting manner and a first side wall of the accommodating recess is embedded in the first recess structure.

2. The heat dissipating device of claim 1, wherein the fixing portion further has a second recess structure, the first recess structure and the second recess structure are formed on opposite sides of the fixing portion, a second side wall of the accommodating recess is embedded in the second recess structure after the base and the heat dissipating fin are combined with each other by the punching process, and the first side wall is opposite to the second side wall.

3. The heat dissipating device of claim 2, wherein the fixing portion further has a third recess structure, the third recess structure is formed on a bottom of the fixing portion and located between the first recess structure and the second recess structure, the accommodating recess has a protruding structure, the protruding structure is located between the first side wall and the second side wall, and the third protruding structure is embedded in the third recess structure after the base and the heat dissipating fin are combined with each other by the punching process.

4. The heat dissipating device of claim 1, wherein the base and the heat dissipating fin are made of aluminum.

5. The heat dissipating device of claim 1, wherein opposite sides of the heat dissipating portion have symmetrical or asymmetrical wave-shaped surface structures.

6. The heat dissipating device of claim 1, wherein the heat dissipating fin is formed by an extrusion process or a die casting process.

7. The heat dissipating device of claim 1, wherein the fixing portion is T-shaped.
